(19) United States
(12) Patent Application Publication
(10) Pub. No.: US 2025/0056933 A1
(43) Pub. Date: Feb. 13, 2025

(54) MOUNTING STRUCTURES FOR EDGE-EMITTING SEMICONDUCTOR DEVICES

(71) Applicant: CreeLED, Inc., Durham, NC (US)

(72) Inventors: David Suich, Durham, NC (US); Michael Check, Holly Springs, NC (US); Colin Blakely, Raleigh, NC (US); Andre Pertuit, Raleigh, NC (US); Joseph G. Sokol, Durham, NC (US); Robert Wilcox, Rolesville, NC (US)

(21) Appl. No.: 18/446,656

(22) Filed: Aug. 9, 2023

(51) Int. Cl. H01L 33/48; H01L 33/62

(52) U.S. Cl. CPC H01L 33/483; H01L 33/62; H01L 2933/0091

(57) ABSTRACT

Semiconductor devices and more particularly mounting structures for edge-emitting semiconductor devices are disclosed. Exemplary edge-emitting semiconductor devices include light-emitting diode (LED) edge emitters. Mounting structures include submounts with recesses configured to receive edge-emitting semiconductor devices such that emitting edges are positioned toward desired emission directions. Submount recesses are disclosed that include corresponding electrical connections for edge-emitting semiconductor devices. Multiple edge-emitting semiconductor devices are mechanically supported and electrically connected within a single recess or with multiple recesses. Corresponding devices are disclosed that include arrays of edge-emitting semiconductor devices in one or more recesses.

### FIELD OF THE DISCLOSURE

The present disclosure relates to semiconductor devices and more particularly to mounting structures for edge-emitting semiconductor devices.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have been widely adopted in various illumination contexts, for backlighting of liquid crystal display (LCD) systems (e.g., as a substitute for cold cathode fluorescent lamps), and for direct-view LED displays. Applications utilizing LED arrays further include vehicular headlamps, roadway illumination, light fixtures, and various indoor, outdoor, and specialty contexts. Desirable characteristics of LED devices include high luminous efficacy, long lifetime, and color gamut.

LEDs convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. Multiple color LED packages have been developed that include LED chips with different emission colors arranged within a same package structure. In certain applications, the LED chips can be arranged in close proximity to one another on a common submount, which can add complexity for corresponding electrical connections. As LED applications continue to advance, challenges exist in producing high quality light with desired emission characteristics while also providing high light emission efficiency.

The art continues to seek improved LEDs and solid-state lighting devices having desirable illumination characteristics capable of overcoming challenges associated with conventional lighting devices.

### SUMMARY

The present disclosure relates to semiconductor devices and more particularly to mounting structures for edge-emitting semiconductor devices. Exemplary edge-emitting semiconductor devices include light-emitting diode (LED) edge emitters. Mounting structures include submounts with recesses configured to receive edge-emitting semiconductor devices such that emitting edges are positioned toward desired emission directions. Submount recesses may include corresponding electrical connections for edge-emitting semiconductor devices. Multiple edge-emitting semiconductor devices may be mechanically supported and electrically connected within a single recess or with multiple recesses. Corresponding devices are disclosed that include arrays of edge-emitting semiconductor devices in one or more recesses.

In one aspect, an LED device comprises: an edge-emitting LED chip comprising: an n-type layer, an active layer, and a p-type layer; and a first edge and an opposing second edge, the active layer extending lengthwise between the first edge and the second edge; and a submount with a recess, the edge-emitting LED chip residing at least partially within the recess such that the edge-emitting LED chip is mechanically supported and electrically coupled to the submount within the recess. In certain embodiments: the edge-emitting LED chip further comprises an n-contact on the n-type layer and a p-contact on the p-type layer; and the n-contact and the p-contact are electrically coupled to the submount within the recess. The LED device may further comprise a first electrical connection and a second electrical connection on sidewalls of the recess, wherein the p-contact is electrically coupled to the first electrical connection and the n-contact is electrically coupled to the second electrical connection. In certain embodiments, portions of the first electrical connection and portions of the second electrical connection extend on a top surface of the submount and away from the recess to form contact pads. The LED device may further comprise vias that provide electrically conductive paths for the first electrical connection and the second electrical connection to a bottom surface of the submount. In certain embodiments, the second edge is in contact with a floor of the recess. In certain embodiments, the second edge is spaced from a floor of the recess. In certain embodiments, sidewalls of the recess are angled such that the floor of the recess has a smaller lateral dimension than a lateral dimension of the recess at a top surface of the submount. The LED device may further comprise a reflective material between the second edge and the floor of the recess. In certain embodiments, the floor of the recess is curved.

In another aspect, an LED device comprises: a plurality of edge-emitting LED chips, each edge-emitting LED chip comprising: an n-type layer, an active layer, and a p-type layer; and a first edge and an opposing second edge, the active layer extending lengthwise between the first edge and the second edge; and a submount with a recess, the plurality of edge-emitting LED chips residing at least partially within the recess. In certain embodiments, the plurality of edge-emitting LED chips comprises a first edge-emitting LED chip and a second edge-emitting LED chip within the recess, wherein the first edge-emitting LED chip is configured to provide a different emission wavelength than the second edge-emitting LED chip. The LED device may further comprise a separate first electrical connection and a separate second electrical connection in the recess for each edge-emitting LED chip of the plurality of edge-emitting LED chips. The LED device may further comprise a common first electrical connection and a common second electrical connection in the recess for each edge-emitting LED chip of the plurality of edge-emitting LED chips. The LED device may further comprise a common first electrical connection and multiple second electrical connections in the recess for each edge-emitting LED chip of the plurality of edge-emitting LED chips.

In another aspect, an LED device comprises: a submount comprising a top surface, a first recess that extends into the submount from the top surface, and a second recess that extends into the submount from the top surface; a first edge-emitting LED chip at least partially within the first recess; and a second edge-emitting LED chip at least partially within the second recess. In certain embodiments, the first edge-emitting LED chip is mechanically supported and electrically coupled to the submount within the first recess, and the second edge-emitting LED chip is mechanically supported and electrically coupled to the submount within the second recess. In certain embodiments, the first recess comprises a different lateral width than the second recess. In certain embodiments, the top surface of the submount comprises a black surface. In certain embodiments, the submount comprises material that is transparent to light from the first edge-emitting LED chip and the second edge-emitting LED chip. In certain embodiments, recess floors of the first recess and the second recess are open through a bottom surface of the submount. In certain embodiments, the top surface of the submount comprises light-scattering materials.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a perspective view of an exemplary edge-emitting light-emitting diode (LED) chip according to principles of the present disclosure.

FIG. 2A is a cross-sectional view of a portion of an LED device for receiving the LED chip of FIG. 1.

FIG. 2B is a cross-sectional view of the LED device of FIG. 2A after the edge-emitting LED chip of FIG. 1 is mounted thereon.

FIG. 3 is a cross-sectional view of an LED device that is similar to the LED device of FIG. 2A except the sidewalls of the recess are angled within the submount.

FIG. 4 is a cross-sectional view of an LED device that is similar to the LED device of FIG. 3 except the recess floor is curved or rounded.

FIG. 5 is a top perspective view of an LED device that is similar to the LED device of FIG. 2B and includes multiple edge-emitting LED chips arranged in an array.

FIG. 6 is a top perspective view of an LED device that is similar to the LED device of FIG. 5 for embodiments where recesses are formed with different sizes to accommodate different sizes of corresponding edge-emitting LED chips.

FIG. 7 is a top perspective view of an LED device that is similar to the LED device of FIG. 5 for embodiments where first and second electrical connections are continuous along the recesses.

FIG. 8 is a top perspective view of an LED device that is similar to the LED device of FIG. 5 where the submount is shown without the edge-emitting LED chips of FIG. 5 for illustrative purposes.

FIG. 9 is a top perspective view of an LED device that is similar to the LED device of FIG. 5 where the first electrical connection is continuous for each of the recesses and multiple second electrical connections are provided within each of the recesses.

FIG. 10 is a top perspective view of an LED device that is similar to the LED device of FIG. 5 except a separate recess is provided for each edge-emitting LED chip.

FIG. 11 is a top perspective view of an LED device that is similar to the LED device of FIG. 10 except the material of the submount is configured to be transparent to light.

FIG. 12 is a top perspective view of an LED device that is similar to the LED device of FIG. 10 except the material of the submount is configured to diffuse and/or reflect light.

FIG. 13 is a top perspective view of an LED device that is similar to the LED device of FIG. 5 and where the first and second electrical connections form contact pads on the top surface of the submount.

FIG. 14A is a top perspective view of an LED device that is similar to the LED device of FIG. 5 and where the first and second electrical connections further include vias that facilitate electrically conductive paths to the bottom surface of the submount.

FIG. 14B is a bottom view of the LED device of FIG. 14A.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to semiconductor devices and more particularly to mounting structures for edge-emitting semiconductor devices. Exemplary edge-emitting semiconductor devices include light-emitting diode (LED) edge emitters. Mounting structures include submounts with recesses configured to receive edge-emitting semiconductor devices such that emitting edges are positioned toward desired emission directions. Submount recesses may include corresponding electrical connections for edge-emitting semiconductor devices. Multiple edge-emitting semiconductor devices may be mechanically supported and electrically connected within a single recess or with multiple recesses. Corresponding devices are disclosed that include arrays of edge-emitting semiconductor devices in one or more recesses.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group Ill nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In some embodiments, the active LED structure emits blue light with a peak wavelength range in a range of 430 nanometers (nm) to 480 nm. In other embodiments, the active LED structure emits green light with a peak wavelength in a range of 500 nm to 570 nm. In other embodiments, the active LED structure emits orange and/or red light with a peak wavelength range of 600 nm to 700 nm. In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications. Near-IR and/or IR wavelengths for LED structures of the present disclosure may have wavelengths above 700 nm, such as in a range from 700 nm to 1000 nm, or more.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of from 2500 Kelvin (K) to 10,000 K. In certain embodiments, lumiphoric materials having cyan, green, amber, yellow, orange, and/or red peak wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AISiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, one or more surfaces of LED chips may be conformally coated with one or more lumiphoric materials, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

According to aspects of the present disclosure, LED structures may be incorporated within packages that may include one or more elements, such as lumiphoric materials, encapsulants, light-altering materials, lens, and electrical contacts, among others, that are provided with one or more LED chips. In certain aspects, packages may include a support member, such as a submount or a lead frame. Light-altering materials may be arranged within packages to reflect on otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. In certain aspects, the particles may have an index or refraction that is configured to refract light emissions in a desired direction. In certain aspects light-reflective particles may also be referred to as light-scattering particles. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast. In certain embodiments, the light-altering material includes both light-reflective material and light-absorbing material suspended in a binder.

In LED display applications, LED chips are typically individually addressable to provide color-changing, dynamic spectral tuning, and the like. When LED chips having different emission wavelengths are arranged in close proximity to one another, practical limitations exist for packaging the LED chips, providing electrical connections, and/or thermal management. Conventional devices for such applications may include separately packaged LED components that are clustered together, where each separately packaged LED component may include a single LED chip or a grouping of different LED chips. However, each separately packaged LED component typically includes its own submount and encapsulant, thereby providing spatial limitations in how close the separately packaged LED components may be arranged together.

Aspects of the present disclosure relate to edge-emitting semiconductor devices, such as LED chips in the form of LED edge emitters. For such edge-emitting devices, electrical connections may be provided along sidewalls or device edges. In this manner, a first edge of the semiconductor device may be configured to be mounted to another surface such that emissions are directed out of an opposite edge that forms a primary emission surface. In such embodiments, a plane corresponding to the active layer of the LED may be mounted on its edge, such as generally perpendicular to the mounting surface.

In this regard, the edge-emitting LEDs may be arranged in close proximity to one another with a pitch not possible by conventional means. In certain embodiments, LED chips as LED edge emitters are capable of being arranged with a super fine pitch within an LED array. For example, a pitch, or spacing, between next-adjacent LED chips may be as low as 10 nm or in a range from 10 nm to 1000 nm with tolerances of +10%. Such fine pitch capabilities are well suited for providing LED chips as pixels of LED displays with increased resolution.

Methods of manufacturing such edge-emitting semiconductor devices involve forming device and contact layers at a wafer level, rotating the wafer level structure, and performing singulation from the perspective of edges of the device and contact layers. Such methods are further described in U.S. patent application Ser. No. 18/345,166, filed Jun. 30, 2023, the contents of which are incorporated by reference herein in their entirety. Embodiments of the present disclosure are discussed in the context of LEDs; however, the principles described are also applicable to other devices, such as lasers or other semiconductor devices. Emission wavelengths for such edge-emitting semiconductor devices include various wavelengths across the electromagnetic spectrum, including visible light, infrared, and ultraviolet emissions.

According to aspects of the present disclosure, mounting structures for edge-emitting semiconductor devices include submounts with recesses configured to receive edge-emitting devices. By forming such recesses into a surface of the submount, edge-emitting semiconductor devices may be precisely arranged and/or aligned relative to the recesses and to one another. When mounted, at least a portion or sometimes all of an edge-emitting semiconductor device resides within a recess with a primary emission edge being positioned to emit light away from the recess. In this manner, the recess may be referred to as a slot or a slot trench that receives the edge-emitting semiconductor device. The recess may further include corresponding electrical connections for sidewalls of the edge-emitting semiconductor device. In this regard, the recess may provide both mechanical support and electrical connections for the edge-emitting semiconductor device. In certain embodiments, multiple edge-emitting semiconductor devices may be mechanically supported and electrically connected within a single recess.

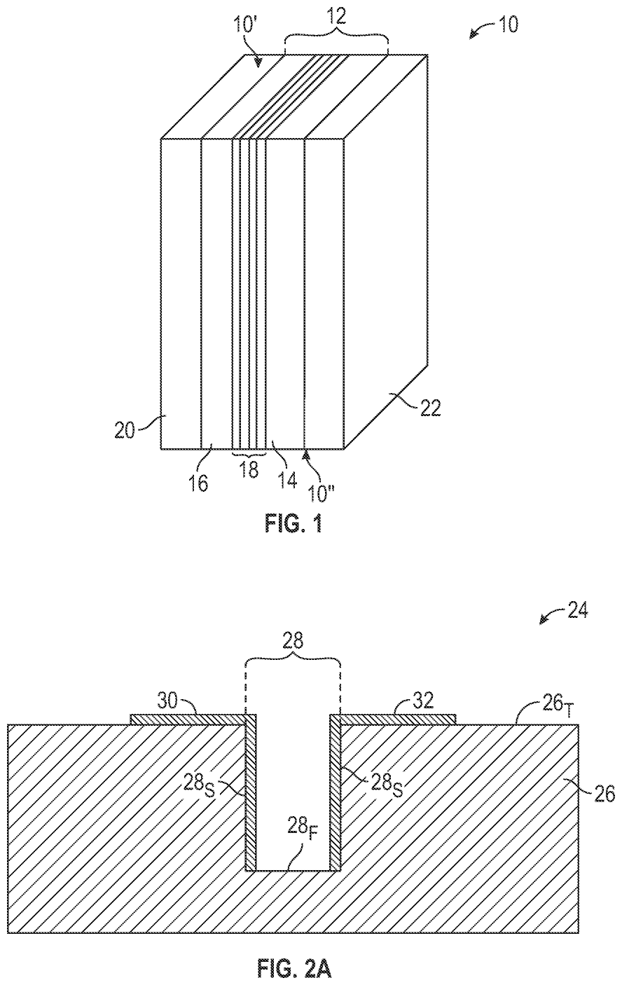

FIG. 1 is a perspective view of an exemplary edge-emitting LED chip 10 according to principles of the present disclosure. While the following description is provided in the context of LED applications, the principles disclosed may also be applicable to other edge-emitting semiconductor devices. The LED chip 10 includes an active LED structure 12 formed by a sequence of epitaxial layers. For illustrative purposes, an n-type layer 14, a p-type layer 16, and an active layer 18 therebetween are illustrated. The active layer 18 may comprise a single quantum well structure or a multiple quantum well structure. As described above, it is understood an active LED structure 12 may include many additional layers.

As illustrated, the LED chip 10 includes a p-contact 20, or p-contact layer, that is on and electrically coupled to the p-type layer 16. In certain embodiments, the p-contact 20 may be blanket deposited to cover the p-type layer 16. The LED chip 10 may also include an n-contact 22, or n-contact layer, that is on and electrically coupled to the n-type layer 14. In certain embodiments, the n-contact 22 may be blanket deposited to cover the n-type layer 14. The p-contact 20 and the n-contact 22 may include many different materials such as gold (Au), copper (Cu), nickel (Ni), In, Al, Ag, tin (Sn), platinum (Pt), chromium (Cr) or alloys or combinations thereof. In still other embodiments, the p-contact 20 and the n-contact 22 may comprise electrically conducting oxides and transparent conducting oxides such as indium tin oxide (ITO), nickel oxide (NiO), zinc oxide (ZnO), cadmium tin oxide, indium oxide, tin oxide, magnesium oxide, ZnGa₂O₄, ZnO₂/Sb, Ga₂O₃/Sn, AglnO₂/Sn, In₂O₃/Zn, CuAlO₂, LaCuOS, CuGaO₂, and SrCu₂O₂. The p-contact 20 and the n-contact 22 may embody multiple layer structures with multiple layers of any of the materials described above.

For the edge-emitting capabilities of the LED chip 10, the p-contact 20 and the n-contact 22 are formed on opposing faces of the active LED structure 12. In certain embodiments, the n-contact 22 and the p-contact 20 may substantially cover the n-type layer 14 and the p-type layer 16 respectively, such as covering at least 75%, or at least 90%, or at least 95% to 100%. In this manner, light generated within the active layer 18 may be reflected and/or redirected by the n-contact 22 and the p-contact 20 to provide edge emissions. A first edge 10′ of the LED chip 10 may form a primary emission edge, which may also be referred to as a light-emitting edge, and the first edge 10′ may include portions of the n-type layer 14, the p-type layer 16, and the active layer 18. A second edge 10″ is defined on an opposite side of the LED chip 10 from the first edge 10′. The second edge 10″ may form a primary mounting edge for the LED chip 10. As illustrated, in the edge-emitting arrangement, the active layer 18 extends lengthwise between the first edge 10′ and the second edge 10″ such that the active layer 18 is perpendicular to a mounting surface of the LED chip 10.

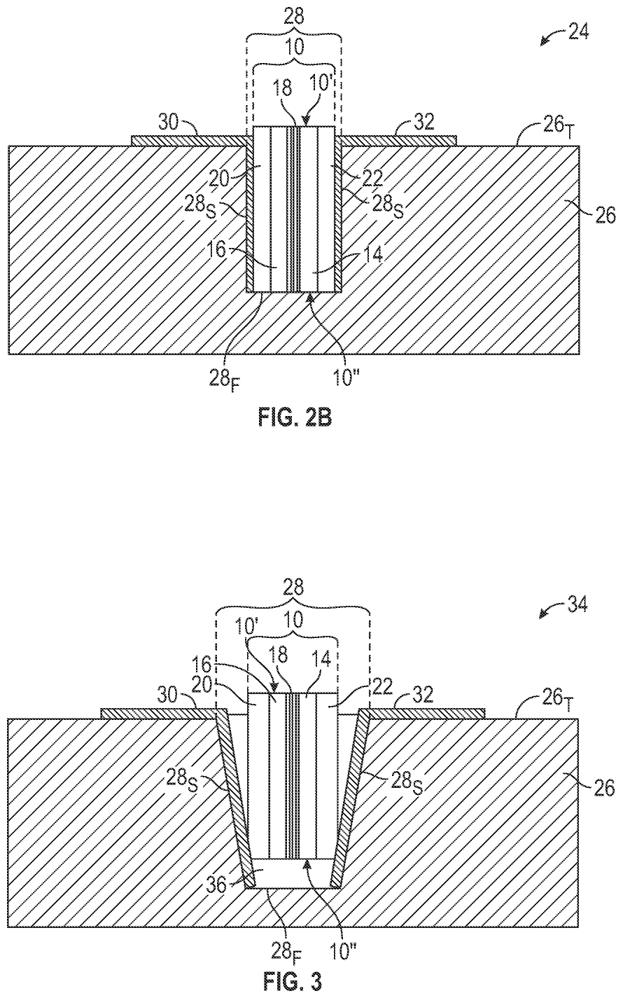

FIG. 2A is a cross-sectional view of a portion of an LED device 24 for receiving the LED chip 10 of FIG. 1. The LED device 24 includes a submount 26 and a recess 28 that is sized to receive the LED chip 10 of FIG. 1. The recess 28 may form an opening that extends below a top surface 26T of the submount 26. In certain embodiments, the recess 28 may form a slot or a trench. The LED device 24 may further include first and second electrical connections 30, 32 configured to electrically couple with the n-contact 22 and the p-contact 20 of FIG. 1. In certain embodiments, the first and second electrical connections 30, 32 are configured to extend within the recess 28. For example, the first and second electrical connections 30, 32 may extend along sidewalls 28s of the recess 28 in a direction away from the top surface 26T. The first and second electrical connections 30, 32 may partially extend on the sidewalls 28s, or the first and second electrical connections 30, 32 may extend all the way to a recess floor 28F. In further embodiments, portions of the of the first and second electrical connections 30, 32 may extend outside the recess 28 and along the top surface 26T of the submount 26. In certain embodiments, the first and second electrical connections 30, 32 may embody electrical traces that are patterned on the submount 26 and within the recess 28. In other embodiments, the first and second electrical connections 30, 32 may embody portions of a lead frame structure.

FIG. 2B is a cross-sectional view of the LED device 24 of FIG. 2A after the edge-emitting LED chip 10 of FIG. 1 is mounted thereon. As illustrated, the LED chip 10 is mounted to reside at least partially within the recess 28. For example, the second edge 10″ is inserted into the recess 28 such that the second edge 10″ is entirely within the recess 28. In certain embodiments, the second edge 10″ may be positioned at or in contact with the recess floor 28F such that the recess floor 28F forms a stopper of the LED chip 10 when inserted into the recess 28. In this manner, a depth of the recess 28 relative to the top surface 26T of the submount 26 may be arranged to control how much of the LED chip 10 may protrude out of the recess 28 from the top surface 26T. In certain embodiments, the LED chip 10 may entirely reside within the recess 28 such that the first edge 10′ is at or below the top surface 26T. Within the recess 28, the p-contact 20 may be electrically coupled to the first electrical connection 30, and the n-contact 22 may be electrically coupled to the second electrical connection 32 along the sidewalls 28_{S}. In this regard, the LED chip 10 may be mechanically supported and electrically coupled to the submount 26 within the recess 28. Portions of the first and second electrical connections 30, 32 may extend on the top surface 26T and away from the recess 28 to route electrical connections to other portions of the LED device 24 and/or provide areas to receive external electrical connections, such as by way of wire bonds.

FIG. 3 is a cross-sectional view of an LED device 34 that is similar to the LED device 24 of FIG. 2A except the sidewalls 28_{S} of the recess 28 are angled within the submount 26. By angling the sidewalls 28_{S} toward one another, the recess floor 28F may be formed with a smaller lateral dimension than a lateral dimension of the recess 28 at the top surface 26T. In this manner, greater manufacturing tolerances may be provided for properly aligning the LED chip 10 within the recess 28. For example, the recess 28 may enable a poka-yoke mounting process where the LED chip 10 may naturally fit within the recess 28. Additionally, the amount of slope for the sidewalls 28s may be configured to control a depth of the LED chip 10 within the recess 28. In the example illustrated by FIG. 3, the second edge 10″ of the LED chip 10 resides above the recess floor 28F as determined by the angle of the sidewalls 28_{S}. In certain embodiments, space between the second edge 10″ and the recess floor 28F may be empty. In other embodiments, space between the second edge 10″ and the recess floor 28F may comprise a reflective material 36 configured to redirect light toward the first edge 10′. The reflective material 36 may comprise a dielectric material, such as light reflective particles in a host material.

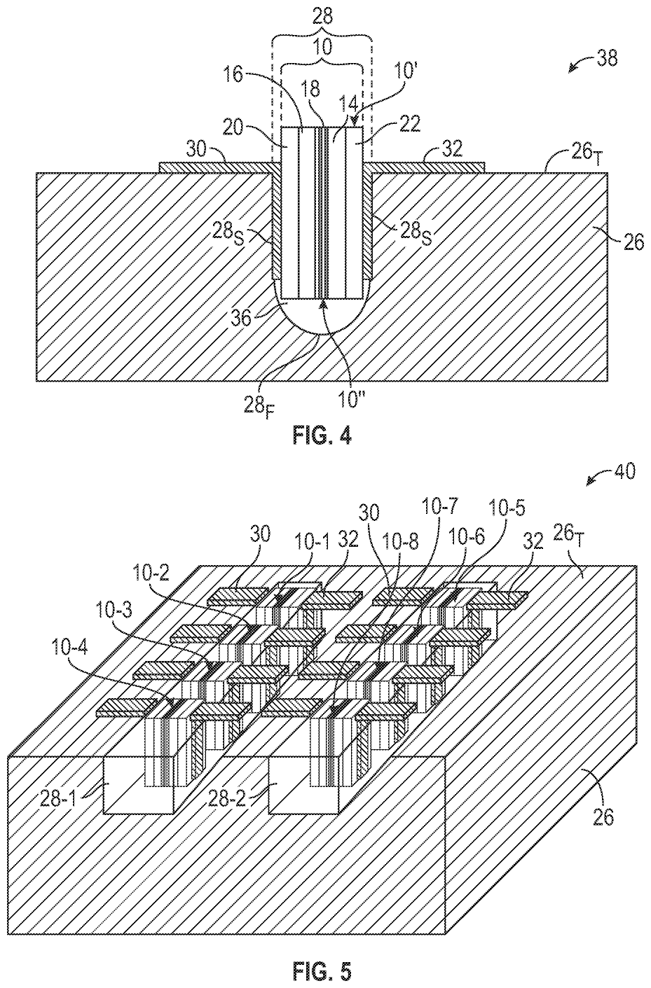

FIG. 4 is a cross-sectional view of an LED device 38 that is similar to the LED device 34 of FIG. 3 except the recess floor 28F is curved or rounded. In this manner, the LED chip 10 may be electrically coupled to the electrical connections 30, 32 along the sidewalls 28_{S}, and the curvature of the recess floor 28F is configured to control a distance between the second edge 10″ and the recess floor 28F. As illustrated, a natural stopping point for placement of the LED chip 10 may be formed where the second edge 10″ contacts portions of the curved surface. In such embodiments, the sidewalls 28_{S} may be perpendicular to the top surface 26T in a similar manner as the LED chip 10 of FIG. 2B. The LED device 38 may further comprise the reflective material 36 as described above for FIG. 3. In other embodiments, the curved recess floor 28F could be implemented in combination with angled sidewalls 28_{S} as described for FIG. 3.

FIG. 5 is a top perspective view of an LED device 40 that is similar to the LED device 24 of FIG. 2B and includes multiple edge-emitting LED chips 10-1 to 10-8 arranged in an array. The LED chips 10-1 to 10-8 may be arranged in one or more recesses 28-1 to 28-2 of the submount 26. For illustrative purposes, the recesses 28-1 to 28-2 are drawn to be visible through portions of the submount 26. In FIG. 5, the edge-emitting LED chips 10-1 to 10-4 are all arranged within a first recess 28-1. To accommodate the multiple edge-emitting LED chips 10-1 to 10-4, the first recess 28-1 may form the shape of an elongated trench along the top surface 26T. Corresponding pairs of the first and second electrical connections 30, 32 may be provided within the recess 28-1 for each LED chip 10-1 to 10-4 to provide individual addressability. In a similar manner, multiple edge-emitting LED chips 10-5 to 10-8 may be arranged in a second recess 28-2 that is separated from the first recess 28-1 by portions of the submount 26, and corresponding pairs of first and second electrical connections 30, 32 may be provided within the second recess 28-2. In certain embodiments, the first and second recesses 28-1 to 28-2 are arranged proximate one another so the edge-emitting LED chips 10-1 to 10-8 collectively form an array across the submount 26. The LED chips 10-1 to 10-8 may all be configured to provide a same emission color for certain applications. In other embodiments, the LED chips 10-1 to 10-8 may be configured to provide multiple emission wavelengths or colors, such as red, green, and blue. In such embodiments, different LED chips 10-1 to 10-8 that are in a same one of the recesses 28-1 to 28-2 may be configured to provide different emission wavelengths or colors. The first and second electrical connections 30, 32 and the recesses 28-1 to 28-2 may be structured according to any of the embodiments described above for FIGS. 2A to 4.

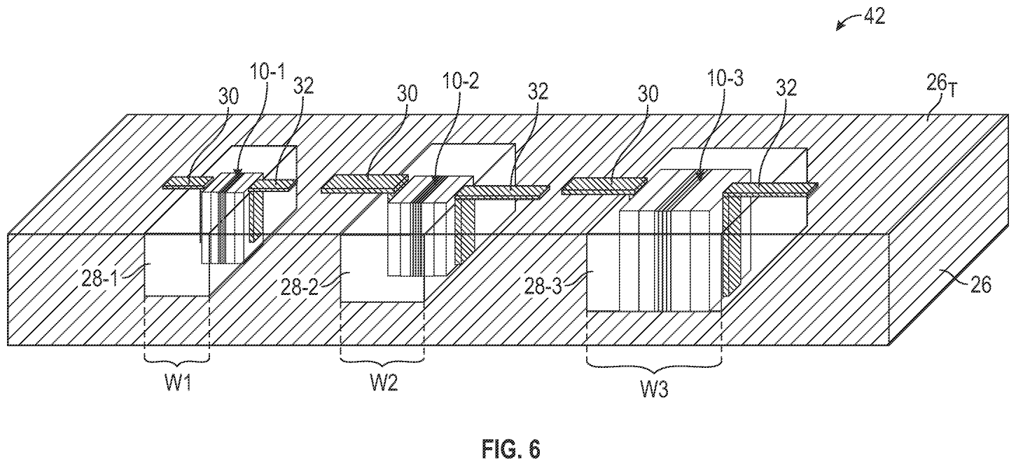

FIG. 6 is a top perspective view of an LED device 42 that is similar to the LED device 40 of FIG. 5 for embodiments where recesses 28-1 to 28-3 are formed with different sizes to accommodate different sizes of corresponding edge-emitting LED chips 10-1 to 10-3. In certain embodiments, edge-emitting LED chips 10-1 to 10-3 may be configured to provide different emission wavelengths or colors. In such cases, dimensions of the edge-emitting LED chips 10-1 to 10-3 may vary depending on structural chip differences related to the different emission wavelengths. By way of example, the edge-emitting LED chip 10-1 may be configured to provide blue emissions, the edge-emitting LED chip 10-2 may be configured to provide green emissions, the edge-emitting LED chip 10-3 may be configured to provide red emissions, and relative widths of the LED chips 10-1 to 10-3 may vary. In this regard, relative lateral widths W1 to W3 of the recesses 28-1 to 28-3 may also vary to accommodate the different chip sizes. As with previous embodiments, the first and second electrical connections 30, 32 and the recesses 28-1 to 28-3 may be structured according to any of the embodiments described above for FIGS. 2A to 4.

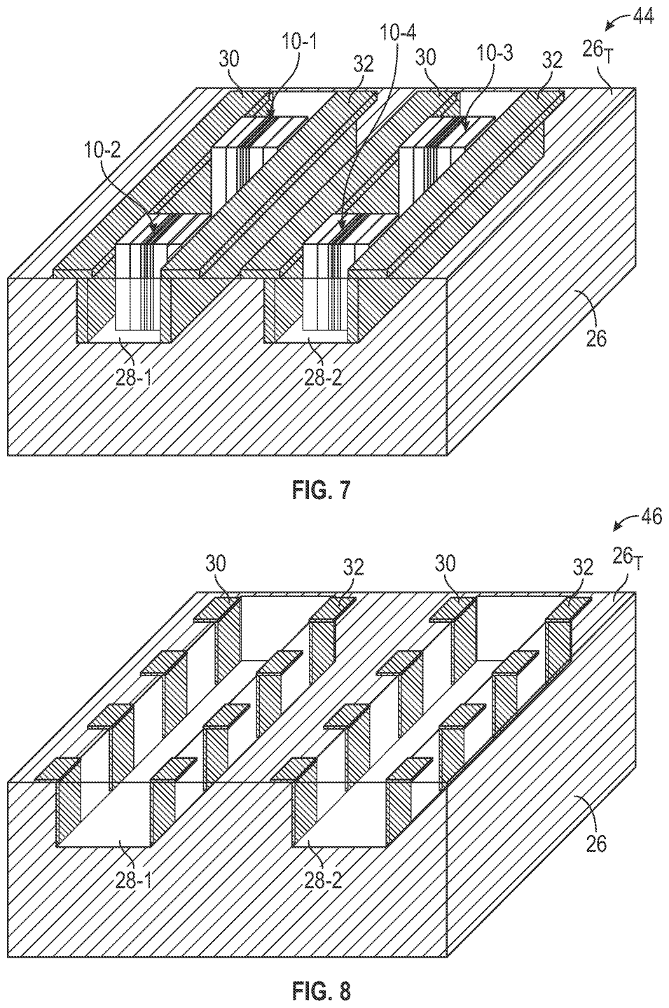

FIG. 7 is a top perspective view of an LED device 44 that is similar to the LED device 40 of FIG. 5 for embodiments where the first and second electrical connections 30, 32 are continuous along the recesses 28-1 to 28-2. In this manner, multiple ones of the edge-emitting LED chips 10-1 to 10-4 may be electrically coupled to a common pair of first and second electrical connections 30, 32. For example, the edge-emitting LED chips 10-1 and 10-2 reside at least partially within the first recess 28-1 and are both connected in parallel to the same pair of first and second electrical connections 30, 32. In a similar manner, the edge-emitting LED chips 10-3 and 10-4 reside at least partially within the second recess 28-2 and are both connected in parallel to another pair of first and second electrical connections 30, 32. As with other embodiments, the first and second electrical connections 30, 32 and the recesses 28-1 to 28-2 may be structured according to any of the embodiments described above for FIGS. 2A to 4.

FIG. 8 is a top perspective view of an LED device 46 that is similar to the LED device 40 of FIG. 5 where the submount 26 is shown without the edge-emitting LED chips 10-1 to 10-8 of FIG. 5 for illustrative purposes. Multiple pairs of first and second electrical connections 30, 32 are provided in a spaced manner along each of the recesses 28-1 and 28-2. In this regard, each pair of first and second electrical connections 30, 32 forms a mounting area for a single edge-emitting LED chip. Accordingly, the LED device 46 of FIG. 8 is configured to provide individual addressability for multiple edge-emitting LED chips. As with other embodiments, the first and second electrical connections 30, 32 and the recesses 28-1 to 28-2 may be structured according to any of the embodiments described above for FIGS. 2A to 4.

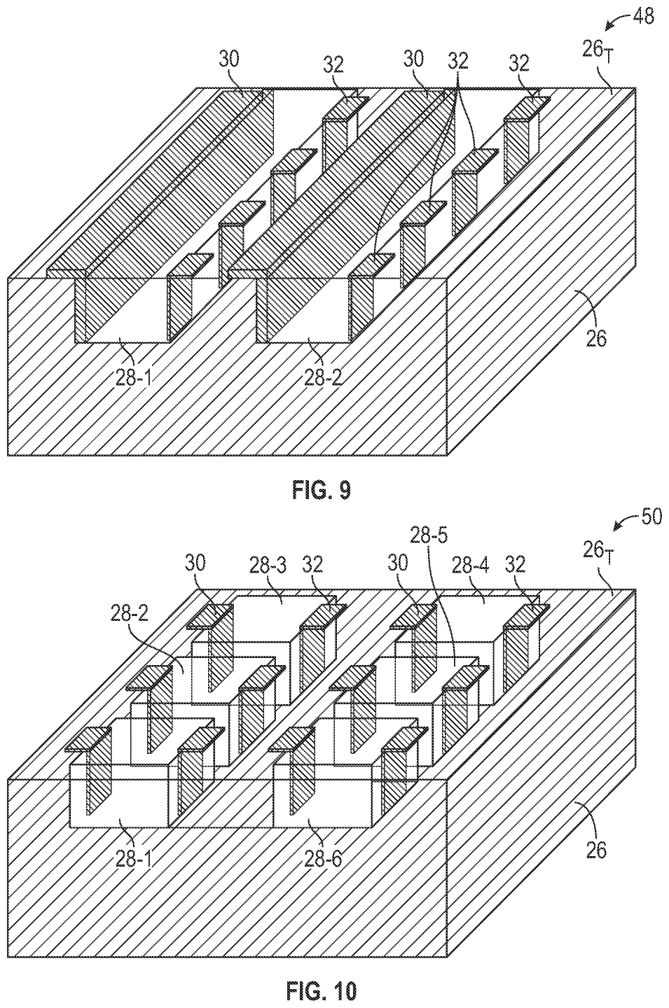

FIG. 9 is a top perspective view of an LED device 48 that is similar to the LED device 40 of FIG. 5 where the first electrical connection 30 is continuous for each of the recesses 28-1 to 28-2 and multiple second electrical connections 32 are provided within each of the recesses 28-1 to 28-2. For illustrative purposes, the edge-emitting LED chips 10-1 to 10-8 of FIG. 5 are omitted. The locations of each of the second electrical connections 32 provide mounting areas for the edge-emitting LED chips. By having the first electrical connection 30 be a common connection along with multiple individual second electrical connections 32, a common anode or a common cathode control arrangement for the edge-emitting LED chips is provided. As with other embodiments, the first and second electrical connections 30, 32 and the recesses 28-1 to 28-2 may be structured according to any of the embodiments described above for FIGS. 2A to 4.

FIG. 10 is a top perspective view of an LED device 50 that is similar to the LED device 40 of FIG. 5 except a separate recess 28-1 to 28-6 is provided for each edge-emitting LED chip. For illustrative purposes, edge-emitting LED chips similar to those of FIG. 5 are omitted; however, it is understood that a single edge-emitting LED chip may reside in each of the recesses 28-1 to 28-6. As illustrated, a separate pair of first and second electrical connections 30, 32 are provided for each of the recesses 28-1 to 28-6. In this regard, the LED device 50 may accommodate multiple and individually controlled LED chips, each of which resides in a separate one of the recesses 28-1 to 28-2. In such a configuration, the material of the submount 26 may provide lateral separation between recesses 28-1 to 28-6 along the top surface 26T of the submount 26. In certain embodiments, the material of the submount 26 may comprise a black or otherwise dark material that is more light-absorbing than light-reflecting. In this manner, the material of the submount 26 may provide enhanced contrast, or a high contrast ratio, between emissions of edge-emitting LED chips within each of the recesses 28-1 to 28-6. In certain embodiments, the material of the submount 26 may be silicone, ceramic, or an organic material. In still further embodiments, the top surface 26T of the submount 26 may comprise a coating or film that is black or otherwise dark for providing the enhanced contrast. As with other embodiments, the first and second electrical connections 30, 32 and the recesses 28-1 to 28-6 may be structured according to any of the embodiments described above for FIGS. 2A to 4.

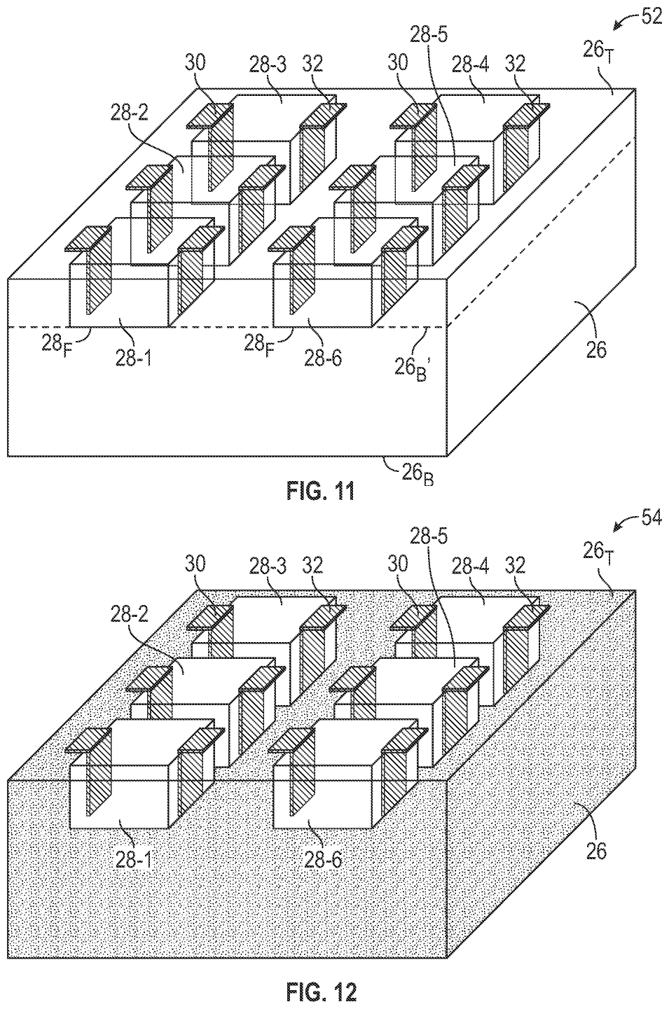

FIG. 11 is a top perspective view of an LED device 52 that is similar to the LED device 50 of FIG. 10 except the material of the submount 26 is configured to be transparent to light. In this regard, the submount 26 may comprise a material such as silicone, a ceramic, and/or an organic material that is configured to permit light from LED chips within the recesses 28-1 to 28-6 to propagate freely through the submount 26. Such an arrangement may be well suited for applications where light mixing is desired between different LED chips before exiting the LED device 52. In certain embodiments, the LED device 52 may be configured to be inverted during operation such that a bottom surface 26B of the submount 26 forms a primary emission face for light exiting the LED device 52. In still further embodiments, a thickness of the submount 26 may be reduced by removing material from the bottom surface 26B such that the bottom surface 26B′ is now positioned at the superimposed dashed lines. For example, the submount 26 may be subjected to a grinding or other removal process where the recess floors 28F of each the recesses 28-1 to 28-6 are exposed or open through the bottom surface 26B′ to permit some light to exit there without passing through the submount 26. As with other embodiments, the first and second electrical connections 30, 32 and the recesses 28-1 to 28-6 may be structured according to any of the embodiments described above for FIGS. 2A to 4.

FIG. 12 is a top perspective view of an LED device 54 that is similar to the LED device 50 of FIG. 10 except the material of the submount 26 is configured to diffuse and/or reflect light. For example, the material of the submount 26 may comprise a material such as silicone, a ceramic, and/or an organic material that also comprises light diffusers mixed therein. In certain embodiments, the submount 26 may comprise a white color. In certain embodiments, the submount 26 may include at least one of fused silica, fumed silica, titanium dioxide (TiO₂), or other light-scattering particles. Such an arrangement may be well suited for applications where the top surface 26T of the submount 26 provides increased brightness and/or increased efficiency of light exiting the LED device 54. In certain embodiments, the top surface 26T of the submount 26 may comprise a coating or film that is white and/or includes light-scattering particles to provide increased reflection and/or diffusion of light. As with other embodiments, the first and second electrical connections 30, 32 and the recesses 28-1 to 28-6 may be structured according to any of the embodiments described above for FIGS. 2A to 4.

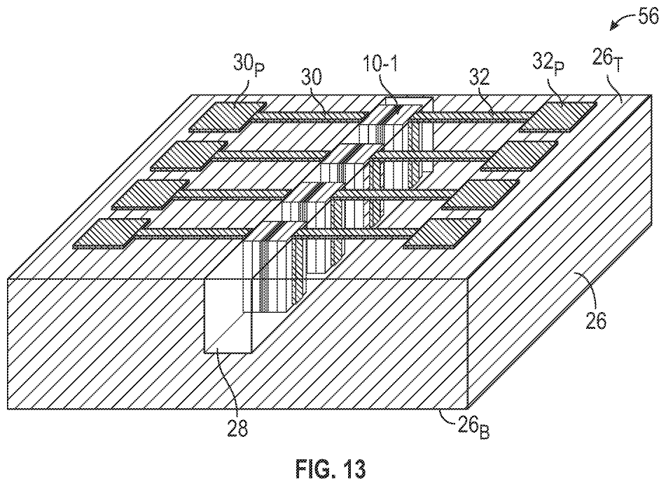

FIG. 13 is a top perspective view of an LED device 56 that is similar to the LED device 40 of FIG. 5 and where the first and second electrical connections 30, 32 form contact pads 30p, 32p on the top surface 26T of the submount 26. In certain embodiments, the first and second electrical connections 30, 32 extend away from the recess 28 and along the top surface 26T a sufficient distance to provide contact areas for receiving external electrical connections. As illustrated, portions of the first and second electrical connections 30, 32 that form the contact pads 30p, 32p may have increased surface area relative to other portions of the first and second electrical connections 30, 32. Accordingly, the contact pads 30P, 32p may be well suited for receiving external electrical connections, such as wire bonds. While only one recess 28 is illustrated, the LED device 56 may include any number of recesses without deviating from the principles disclosed. Furthermore, the first and second electrical connections 30, 32 and the recess 28 may be structured according to any of the embodiments described above for FIGS. 2A to 4.

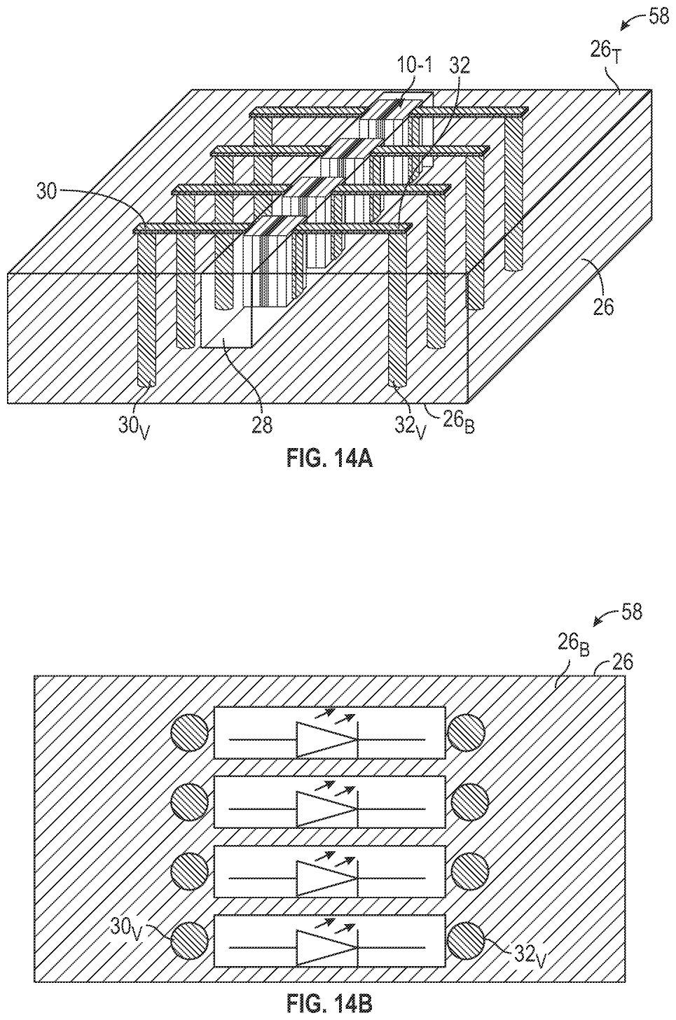

FIG. 14A is a top perspective view of an LED device 58 that is similar to the LED device 40 of FIG. 5 and where the first and second electrical connections 30, 32 further include vias 30v, 32v that facilitate electrically conductive paths to the bottom surface 26B of the submount 26. In this manner, the bottom surface 26B of the submount 26 is configured for receiving external electrical connections. FIG. 14B is a bottom view of the LED device 58 of FIG. 14A. As illustrated in FIGS. 14A and 14B, the vias 30v, 32v of the first and second electrical connections 30, 32 are accessible at the bottom surface 26B of the submount 26. For illustrative purposes, superimposed circuit symbols for LED connections are provided between each pair of the vias 30v, 32v in FIG. 14B. The LED device 58 may be mounted to another surface with corresponding electrical traces. In certain embodiments, such an arrangement is well suited for mounting and or integrating the LED device 58 on boards with LED display drivers and other control circuitry. As with other embodiments, the first and second electrical connections 30, 32 and the recess 28 may be structured according to any of the embodiments described above for FIGS. 2A to 4.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A light-emitting diode (LED) device comprising:
an edge-emitting LED chip comprising:
an n-type layer, an active layer, and a p-type layer; and
a first edge and an opposing second edge, the active layer extending lengthwise between the first edge and the second edge; and
a submount with a recess, the edge-emitting LED chip residing at least partially within the recess such that the edge-emitting LED chip is mechanically supported and electrically coupled to the submount within the recess.

2. The LED device of claim 1, wherein:
the edge-emitting LED chip further comprises an n-contact on the n-type layer and a p-contact on the p-type layer; and
the n-contact and the p-contact are electrically coupled to the submount within the recess.

3. The LED device of claim 2, further comprising a first electrical connection and a second electrical connection on sidewalls of the recess, wherein the p-contact is electrically coupled to the first electrical connection and the n-contact is electrically coupled to the second electrical connection.

4. The LED device of claim 3, wherein portions of the first electrical connection and portions of the second electrical connection extend on a top surface of the submount and away from the recess to form contact pads.

5. The LED device of claim 3, further comprising vias that provide electrically conductive paths for the first electrical connection and the second electrical connection to a bottom surface of the submount.

6. The LED device of claim 1, wherein the second edge is in contact with a floor of the recess.

7. The LED device of claim 1, wherein the second edge is spaced from a floor of the recess.

8. The LED device of claim 7, wherein sidewalls of the recess are angled such that the floor of the recess has a smaller lateral dimension than a lateral dimension of the recess at a top surface of the submount.

9. The LED device of claim 7, further comprising a reflective material between the second edge and the floor of the recess.

10. The LED device of claim 7, wherein the floor of the recess is curved.

11. A light-emitting diode (LED) device comprising:
a plurality of edge-emitting LED chips, each edge-emitting LED chip comprising:
an n-type layer, an active layer, and a p-type layer; and
a first edge and an opposing second edge, the active layer extending lengthwise between the first edge and the second edge; and
a submount with a recess, the plurality of edge-emitting LED chips residing at least partially within the recess.

12. The LED device of claim 11, wherein the plurality of edge-emitting LED chips comprises a first edge-emitting LED chip and a second edge-emitting LED chip within the recess, wherein the first edge-emitting LED chip is configured to provide a different emission wavelength than the second edge-emitting LED chip.

12. (canceled)

13. The LED device of claim 11, further comprising a common first electrical connection and a common second electrical connection in the recess for each edge-emitting LED chip of the plurality of edge-emitting LED chips.

14. The LED device of claim 11, further comprising a common first electrical connection and multiple second electrical connections in the recess for each edge-emitting LED chip of the plurality of edge-emitting LED chips.

15. A light-emitting diode (LED) device comprising:
a submount comprising a top surface, a first recess that extends into the submount from the top surface, and a second recess that extends into the submount from the top surface;
a first edge-emitting LED chip at least partially within the first recess; and
a second edge-emitting LED chip at least partially within the second recess.

16. The LED device of claim 15, wherein the first edge-emitting LED chip is mechanically supported and electrically coupled to the submount within the first recess, and the second edge-emitting LED chip is mechanically supported and electrically coupled to the submount within the second recess.

17. The LED device of claim 15, wherein the first recess comprises a different lateral width than the second recess.

18. The LED device of claim 15, wherein the top surface of the submount comprises a black surface.

19. The LED device of claim 15, wherein the submount comprises material that is transparent to light from the first edge-emitting LED chip and the second edge-emitting LED chip.

20. The LED device of claim 19, wherein recess floors of the first recess and the second recess are open through a bottom surface of the submount.

21. The LED device of claim 15, wherein the top surface of the submount comprises light-scattering materials.

22. The LED device of claim 11, further comprising a separate first electrical connection and a separate second electrical connection in the recess for each edge-emitting LED chip of the plurality of edge-emitting LED chips.
